(19) United States
(12) Patent Application Publication
(10) Pub. No.: US 2009/0260865 A1
(43) Pub. Date: Oct. 22, 2009

(54) MICRO-ELECTROMECHANICAL SYSTEM

(75) Inventor: Yi-Mou Huang, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/405,534

(22) Filed: Mar. 17, 2009

(30) Foreign Application Priority Data
Apr. 21, 2008 (CN) 200810301221.7

(51) Int. Cl. H05K 1/16; H05K 7/02

(52) U.S. Cl. 174/260; 361/760

(57) ABSTRACT

A micro-electromechanical system (MEMS) includes a micro-electromechanical chip, a printed circuit board and a metal wire. The metal wire electrically connects the micro-electromechanical chip and the printed circuit board. A connection distance and a connection angle are defined between the micro-electromechanical chip and the printed circuit board.

### BACKGROUND

1. Field of the Invention

Embodiments of the present disclosure relate to micro-electromechanical systems (MEMS), and more particularly to a system for connecting with the MEMS.

2. Description of Related Art

A MEMS device is generally a nanoscale mechanical structure formed by an etching technique. MEMS devices are used in a variety of applications such as optical display systems, pressure sensors, flow sensors, and charge control actuators. However, as development of the MEMS becomes more diverse and smaller-scale, some devices or systems may require micro-electromechanical chip supports to connect to a printed circuit board at a required angle and distance.

Therefore, what is desired is a MEMS addressing the limitations described.

### BRIEF DESCRIPTION OF THE DRAWINGS

Many aspects of the disclosed MEMS can be better understood with reference to the following drawings. The components in the drawings are not necessarily drawn to scale, the emphasis instead being placed upon clearly illustrating the principles of the present mold separating device. Moreover, in the drawings, like reference numerals designate corresponding parts throughout the several views.

FIG. 1 is a schematic view of a MEMS according to a first embodiment.

FIG. 2 is a sectional view showing the connection between a metal wire and a pad of FIG. 1.

FIG. 3 is a schematic view of a MEMS according to a second embodiment.

FIG. 4 is a schematic view of a MEMS according to a third embodiment.

FIG. 5 is a schematic view of a MEMS according to a fourth embodiment.

### DETAILED DESCRIPTION OF CERTAIN INVENTIVE EMBODIMENTS

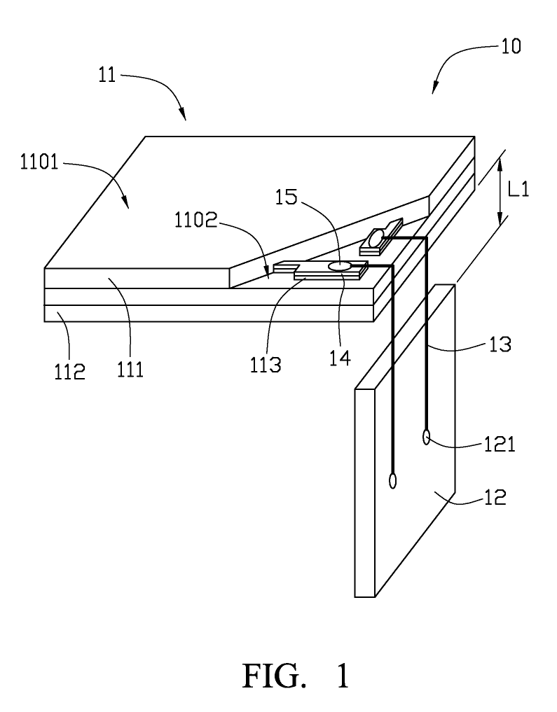

Referring to FIG. 1, a micro-electromechanical system (MEMS) 10 according to a first exemplary embodiment is shown. The MEMS 10 includes a micro-electromechanical chip 11 (hereinafter referred to as chip 11), a printed circuit board 12, and a metal wire 13.

The chip 11 includes a coverage area 1101 and a package area 1102. The coverage area 1101 includes a first plastic element 111 and a second plastic element 112 opposite thereto. The first plastic element 111 and second plastic element 112 provide protection for the microelectronic circuits and devices on the chip 11. The package area 1102 is an area having a pad 113 on the chip 11. In this embodiment, the package area 1102 is disposed in a corner of the chip 11 and not covered by the first plastic element 111. The number of pads 113 is two. However, it may be understood that the MEMS 10 is an example, and different number of pads, circuit elements, and location of the package area 1102 may occur depending on the embodiment.

The printed circuit board 12 includes circuits and driver integrated circuits (ICs). The printed circuit board 12 and chip 11 are separated by a distance. The printed circuit board 12 and chip 11 are angled, and are substantially perpendicular in one embodiment. The printed circuit board 12 includes a connection end 121. The number of connection ends 121 is equal to the number of pads 113. In this embodiment, the printed circuit board 12 includes two connection ends 121. Accordingly, two connection ends 121 are disposed on the center of the printed circuit board 12.

The metal wire 13 may be copper, aluminum, or other suitable materials providing good flexibility and conductivity. One end of the metal wire 13 connects to the pad 113 of the chip 11. Another end of the metal wire 13 connects to the connection end 121 of the printed circuit board 12. The distance between the chip 11 and the printed circuit board 12 defines a connection distance L1. The angle between the chip 11 and the printed circuit board 12 defines a connection angle. The connection distance L1 is the shortest distance between the chip 11 and the printed circuit board 12. Generally, the connection distance L1 may range from about 3-25 mm, and the connection angle can range from 0-90 degrees (°). The diameter of the metal wire 13 may range from about 0.05-0.1 mm. The length of the metal wire 13 exceeds or equals the connection distance L1. The number of the metal wires 13 equals the number of the connection ends 121 and the pads 113. In the illustrated embodiment, the number of metal wires 13 is two, the connection distance L1 is approximately 7-10 mm, and the connection angle is approximately 90 degrees, i.e., the micro-electromechanical chip 11 and the printed circuit board 12 are substantially perpendicular.

The metal wire 13 connects to the connection end 121 by welding or other means. The metal wire 13 connects to the pad 113 by a solder-ball 15 and an under bump metallization (UBM) 14. The UBM 14 is formed on the pad 113 by sputtering, evaporating, chemical plating, electrical plating or other means.

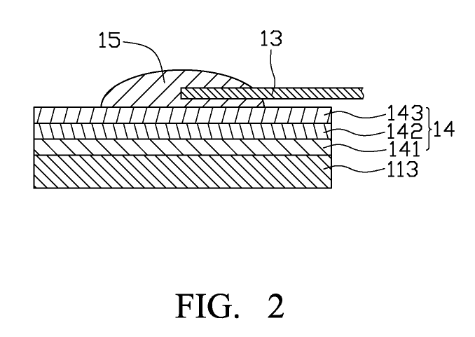

Referring to FIG. 2, the UBM 14 includes an adhesion layer 141, a diffusion barrier layer 142 and a wetting layer 143. The adhesion layer 141 may be selected from the group consisting of chromium (Cr), titanium (Ti), nickel (Ni), and titanium nitride (TiN), or other suitable materials providing good adherence with backing material of the chip 11. The diffusion barrier layer 142 may be selected from the group consisting of tungsten (W), molybdenum (Mo), and, nickel (Ni), or other suitable materials providing a good barrier. The wetting layer 143 may be selected from the group consisting of gold (Au), copper (Cu), and lead (Pb)/tin (Sn), or other suitable materials providing good wetness and a small contact angle with a solder. The thickness of the UBM 14 may range from about 3-30 mm. The adhesion layer 141, the diffusion barrier layer 142, and the wetting layer 143, all may range from about 1-10 mm thick.

The solder-ball 15 connects the pad 113 and the metal wire 13. The dimensions of the solder-ball 15 are less than or equal to the pad 113. For example, the diameter of the solder-ball 15 may range from about 0.2-0.3 mm when the measurement of the pad 113 is 0.44 by 0.54 mm.

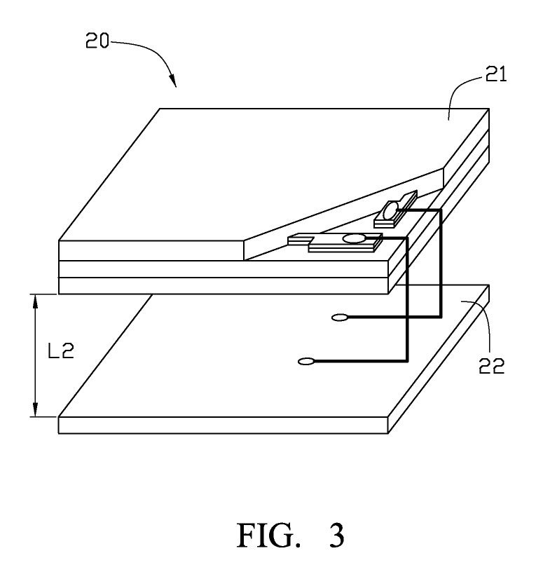

FIG. 3 is a schematic view of a MEMS 20 according to a second embodiment, differing from MEMS 10 only in that a connection distance L2 between the chip 21 and the printed circuit board 22 is in the range from about 15-20 mm, and the angle therebetween is approximately 0°, that is, chip 21 and printed circuit board 22 are substantially parallel.

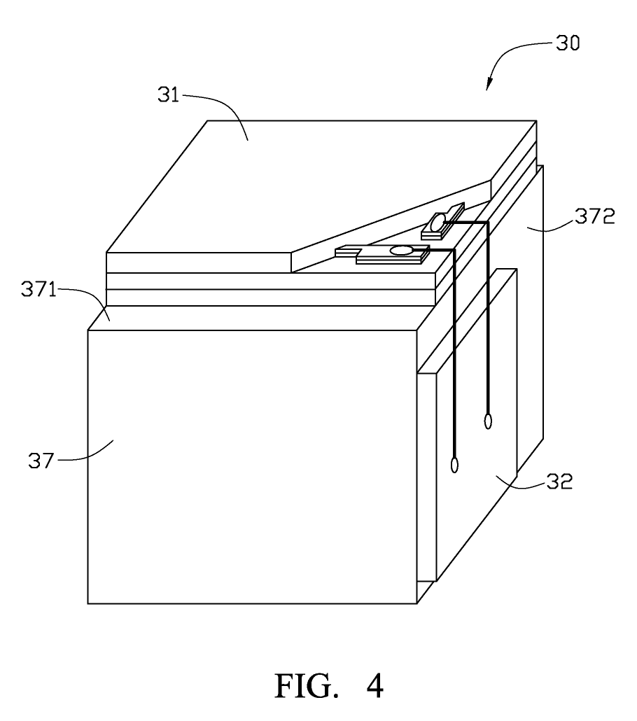

FIG. 4 is a schematic view of a MEMS 30 according to a third embodiment, differing from MEMS 10 only in that the MEMS 30 further includes a support element 37. The support element 37 is disposed between a chip 31 and a printed circuit board 32. Although the support element 37 is shown as being rectangular, it will be appreciated that any other suitable shape, such as, for example, circle, pentagon, hexagon, or other, is equally applicable and well within the scope of the disclosure. The support element 37 can be, for example, a lens module, a motor, or other element. The support element 37 includes a first surface 371 and a second surface 372. The first surface 371 is located adjacent to the second surface 372. The first surface 371 is configured for disposing the chip 31. The second surface 372 is configured for disposing the printed circuit board 32.

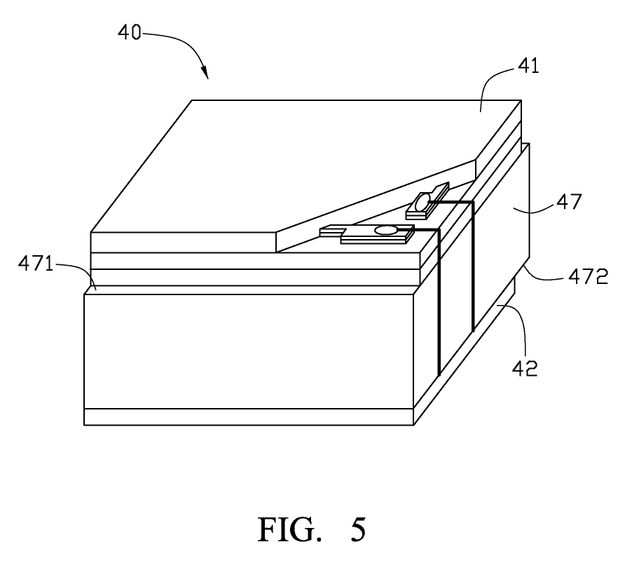

FIG. 5 is a schematic view of a MEMS 40 according to a fourth embodiment, differing from MEMS 20 only in that the MEMS 40 further includes a support element 47. The support element 47 is disposed between a chip 41 and a printed circuit board 42. In the illustrated embodiment, the support element 47 is substantially rectangular, although the support element 47 is shown as being rectangular, it will be appreciated that the support element 47 may be any other suitable shape, such as, for example, circular, pentagonal, hexagonal, or other. The support element 47 can be, for example, a lens module, a motor, or other elements. The support element 47 includes a first surface 471 and a second surface 472. The first surface 471 is located opposite the second surface 472. The first surface 471 is configured for disposing the chip 41. The second surface 472 is configured for disposing the printed circuit board 42.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A micro-electromechanical system (MEMS) comprising:
a micro-electromechanical chip comprising a coverage area and a package area, wherein the micro-electromechanical chip is positioned between a first plastic protective surface and a second plastic protective surface;
a printed circuit board spaced from the micro-electromechanical chip by a distance; and
at least one metal wire electrically connecting the micro-electrical chip to the printed circuit board, wherein the at least one metal wire connects to an under bump metallization (UBM) disposed on a pad positioned on an area of the package area, and wherein the area of the package area is not covered by the first or second plastic protective surface.

2. The system as claimed in claim 1, wherein the UBM comprises an adhesion layer, a diffusion barrier layer and a wetting layer, wherein the adhesion layer is selected from the group consisting of chromium (Cr), titanium (Ti), nickel (Ni), and titanium nitride (TiN), wherein the diffusion barrier layer is selected from the group consisting of tungsten (W), molybdenum (Mo), and nickel (Ni), and wherein the wetting layer is selected from the group consisting of gold (Au), copper (Cu), and lead (Pb)/tin (Sn).

3. The system as claimed in claim 2, wherein the thickness of the UBM ranges from about 3 mm to 30 mm.

4. The system as claimed in claim 1, wherein the distance between the micro-electromechanical chip and the printed circuit board ranges from about 3 mm to 25 mm.

5. The system as claimed in claim 1, wherein the angle between the micro-electromechanical chip and the printed circuit board is about 0 to 90°.

6. The system as claimed in claim 1, wherein the diameter of the metal wire ranges from about 0.05 mm to 0.1 mm.

7. The system as claimed in claim 1, wherein the system further comprises a support element comprising a first surface and a second surface, wherein the first surface is located adjacent or opposite to the second surface, the micro-electromechanical chip is disposed on the first surface, and the printed circuit board is disposed on the second surface.

8. The system as claimed in claim 7, wherein the support element is a lens module or a motor.

9. A micro-electromechanical system (MEMS) comprising:
a micro-electromechanical chip comprising a coverage area and a package area, wherein the micro-electromechanical chip is positioned between a first plastic protective surface and a second plastic protective surface;
a printed circuit board positioned perpendicular to the a micro-electromechanical chip and separated by a distance; and
at least one metal wire electrically connecting the micro-electrical chip to the printed circuit board, wherein the at least one metal wire connects to an under bump metallization (UBM) disposed on a pad positioned on an area of the package area, and wherein the area of the package area is not covered by the first or second plastic protective surface.

10. The system as claimed in claim 9, wherein the UBM comprises an adhesion layer, a diffusion barrier layer and a wetting layer, wherein the adhesion layer is selected from the group consisting of chromium (Cr), titanium (Ti), nickel (Ni), and titanium nitride (TiN), wherein the diffusion barrier layer is selected from the group consisting of tungsten (W), molybdenum (Mo), and nickel (Ni), and wherein the wetting layer is selected from the group consisting of gold (Au), copper (Cu), and lead (Pb)/tin (Sn).

11. The system as claimed in claim 9, wherein the distance between the micro-electromechanical chip and the printed circuit board ranges from about 3 mm to 25 mm, and the diameter of the metal wire ranges from about 0.05 mm to 0.1 mm.

12. The system as claimed in claim 9, wherein the system further comprises a support element comprising a first surface and a second surface, wherein the first surface is located adjacent the second surface, the micro-electromechanical chip is disposed on the first surface, and the printed circuit board is disposed on the second surface.

13. A micro-electromechanical system (MEMS) comprising:
a micro-electromechanical chip comprising a coverage area and a package area, wherein the micro-electromechanical chip is positioned between a first plastic protective surface and a second plastic protective surface;
a printed circuit board positioned parallel to the a micro-electromechanical chip and separated by a distance; and
at least one metal wire electrically connecting the micro-electrical chip to the printed circuit board, wherein the at least one metal wire connects to an under bump metallization (UBM) disposed on a pad positioned on an area of the package area, and wherein the area of the package area is not covered by the first or second plastic protective surface.

14. The system as claimed in claim 13, wherein the UBM comprises an adhesion layer, a diffusion barrier layer and a wetting layer, wherein the adhesion layer is selected from the group consisting of chromium (Cr), titanium (Ti), nickel (Ni) and titanium nitride (TiN), wherein the diffusion barrier layer is selected from the group consisting of tungsten (W), molybdenum (Mo), and nickel (Ni), and wherein the wetting layer is selected from the group consisting of gold (Au), copper (Cu) and lead (Pb)/tin (Sn).

15. The system as claimed in claim 13, wherein the distance between the micro-electromechanical chip and the printed circuit board ranges from about 3 mm to 25 mm, and the diameter of the metal wire ranges from about 0.05 mm to 0.1 mm.

16. The system as claimed in claim 13, wherein the system further comprises a support element comprising a first surface and a second surface, wherein the first surface is located opposite the second surface, the micro-electromechanical chip is disposed on the first surface, and the printed circuit board is disposed on the second surface.
